(19) United States
(12) Patent Application Publication
(10) Pub. No.: US 2018/0278221 A1
(43) Pub. Date: Sep. 27, 2018

(54) DIFFERENTIAL AMPLIFIER CIRCUIT

(71) Applicant: ABLIC Inc., Chiba-shi (JP)

(72) Inventors: Toshiyuki TSUZAKI, Chiba-shi (JP); Masakazu SUGIURA, Chiba-shi (JP)

(21) Appl. No.: 15/927,508

(22) Filed: Mar. 21, 2018

(30) Foreign Application Priority Data
Mar. 24, 2017 (JP) 2017-059969

(51) Int. Cl. H03F 3/45

(52) U.S. Cl. CPC H03F 3/45183; H03F 3/45672

(57) ABSTRACT

To perform a rail-to-rail input operation, provided is a differential amplifier circuit including a first differential input pair and a second differential input pair which has a threshold value different from that of the first differential input pair. Both the differential input pairs do not operate at the same time. A transistor is connected between the first differential input pair and a current source to achieve a configuration in which the first differential input pair and the second differential input pair do not operate at the same time.

### RELATED APPLICATIONS

This application claims priority under 35 U.S.C. § 119 to Japanese Patent Application No. 2017-059969 filed on Mar. 24, 2017, the entire content of which is hereby incorporated by reference.

### BACKGROUND OF THE INVENTION

### 1. Field of the Invention

The present invention relates to a differential amplifier circuit, and more particularly, to a circuit configured to perform a rail-to-rail input operation.

### 2. Description of the Related Art

A differential amplifier circuit is used in electronic devices for various purposes. An input signal voltage is different depending on the purpose, and is, for example, near a GND voltage or near a power supply voltage. A rail-to-rail input operation is, accordingly, important in the differential amplifier circuit.

FIG. 5 is a circuit diagram of a related-art differential amplifier circuit disclosed in Japanese Patent Application Laid-open No. Hei 8-256026. The related-art differential amplifier circuit includes an inverting input terminal 511, a non-inverting input terminal 512, an output terminal 513, a power supply voltage 509, a GND voltage 510, NMOS depletion transistors 501 and 502, NMOS enhancement transistors 503, 504, 507, and 508, and PMOS enhancement transistors 505 and 506.

The NMOS depletion transistors 501 and 502 form a first differential input pair 521. The NMOS transistors 503 and 504 form a second differential input pair 522. The NMOS transistor 507 serves as a current source for supplying a current that flows through the first differential input pair 521. The NMOS transistor 508 serves as a current source for supplying a current that flows through the second differential input pair 522. The PMOS transistors 505 and 506 form a load of the first differential input pair 521 and the second differential input pair 522 described above.

In FIG. 6, operation of the related-art differential amplifier circuit is shown. In general, the differential amplifier circuit is used for negative feedback, and hence the non-inverting input terminal 512 and the inverting input terminal 511 are virtually short-circuited, with the result that the non-inverting input terminal 512 and the inverting input terminal 511 have almost the same voltage. This voltage is defined as a common-mode input voltage VCOM. The vertical axis of the graph of FIG. 6 indicates the common-mode input voltage VCOM, and the horizontal axis thereof indicates the first differential input pair 521 and the second differential input pair 522.

When the common-mode input voltage VCOM becomes near the GND voltage, the NMOS transistor 508 serving as the current source for the second differential input pair 522 enters a non-saturation state, thereby being not capable of supplying current since the second differential input pair 522 is formed of the NMOS enhancement transistors 503 and 504, and hence, the differential amplifier circuit is not capable of amplifying an input signal.

In order to achieve rail-to-rail input, the first differential input pair 521 formed of the NMOS depletion transistors is connected in parallel to the second differential input pair 522 formed of the NMOS enhancement transistors. Even when the common-mode input voltage VCOM becomes near the GND voltage, the NMOS transistor 507 serving as the current source for the first differential input pair 521 does not enter the non-saturation state, thereby being capable of supplying current since the first differential input pair 521 is formed of the NMOS depletion transistors 501 and 502, and hence, rail-to-rail input is achieved.

However, in the differential amplifier circuit in Japanese Patent Application Laid-open No. Hei 8-256026, depending on a value of the common-mode input voltage VCOM, the currents are supplied from the current sources to both the first differential input pair 521 formed of the NMOS depletion transistors and the second differential input pair 522 formed of the NMOS enhancement transistors, with the result that both differential input pairs operate at the same time.

### SUMMARY OF THE INVENTION

In order to solve the related-art problem, a differential amplifier circuit according to one embodiment of the present invention has the following configuration. The differential amplifier circuit includes: an inverting input terminal; a non-inverting input terminal; an output terminal; a first differential input pair configured to receive input from the inverting input terminal and the non-inverting input terminal; a second differential input pair configured to receive input from the inverting input terminal and the non-inverting input terminal, the second differential input pair including transistors that have a threshold value different from a threshold value of transistors included in the first differential input pair; a current source configured to supply a current that flows to the differential input pair; and a switch provided between the first differential input pair and the current source, and is configured to be turned on and off in accordance with a voltage across the inverting input terminal and the non-inverting input terminal.

In the differential amplifier circuit of the present invention, irrespective of a value of the common-mode input voltage VCOM, a current from the current source is supplied to only one of the first differential input pair formed of the NMOS depletion transistors and the second differential input pair formed of the NMOS enhancement transistors. As a result, both differential input pairs do not operate at the same time.

### BRIEF DESCRIPTION OF THE DRAWINGS

FIG. 1 is a circuit diagram for illustrating an example of a differential amplifier circuit according to a first embodiment of the present invention.

FIG. 2 is a graph for showing circuit operation of the first embodiment.

FIG. 3 is a circuit diagram for illustrating an example of a differential amplifier circuit according to a second embodiment of the present invention.

FIG. 4 is a graph for showing circuit operation of the second embodiment.

FIG. 5 is a circuit diagram for illustrating an example of a related-art differential amplifier circuit.

FIG. 6 is a graph for showing circuit operation of the related art.

### DETAILED DESCRIPTION OF THE EMBODIMENTS

Now, embodiments of the present invention are described with reference to the drawings.

### First Embodiment

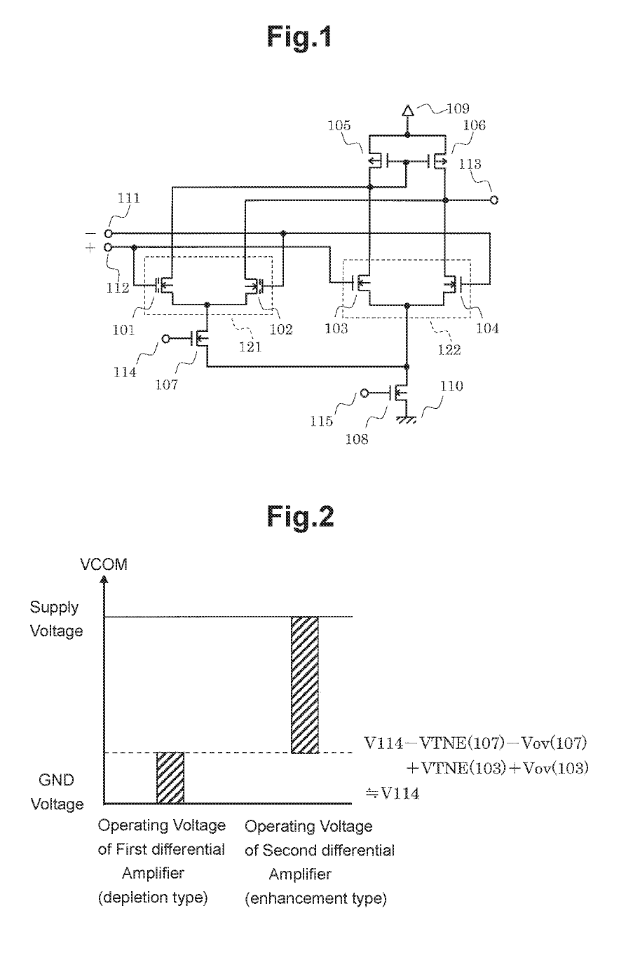

FIG. 1 is a circuit diagram for illustrating a differential amplifier circuit according to a first embodiment of the present invention.

The differential amplifier circuit of the first embodiment includes an inverting input terminal 111, a non-inverting input terminal 112, an output terminal 113, a power supply voltage 109, a GND voltage 110, NMOS depletion transistors 101 and 102, NMOS enhancement transistors 103, 104, 107, and 108, and PMOS enhancement transistors 105 and 106.

A gate of the NMOS depletion transistor 101 is connected to the non-inverting input terminal 112. A gate of the NMOS depletion transistor 102 is connected to the inverting input terminal 111. A source of the NMOS depletion transistor 101 and a source of the NMOS depletion transistor 102 are connected to each other. The NMOS depletion transistors 101 and 102 form a first differential input pair 121. A gate of the NMOS transistor 103 is connected to the non-inverting input terminal 112. A gate of the NMOS transistor 104 is connected to the inverting input terminal 111. A source of the NMOS transistor 103 and a source of the NMOS transistor 104 are connected to each other. The NMOS transistors 103 and 104 form a second differential input pair 122.

A drain of the NMOS transistor 107 is connected to the source of the NMOS depletion transistor 101 and the source of the NMOS depletion transistor 102. A gate of the NMOS transistor 107 is connected to a switching voltage input 114. A source of the NMOS transistor 107 is connected to a drain of the NMOS transistor 108. The NMOS transistor 107 serves as a switch used for switching the first differential input pair 121 and the second differential input pair 122. The drain of the NMOS transistor 108 is connected to the source of the NMOS transistor 103 and the source of the NMOS transistor 104. A gate of the NMOS transistor 108 is connected to a bias voltage input 115. A source of the NMOS transistor 108 is connected to the GND voltage 110. The NMOS transistor 108 serves as a current source for supplying a current that flows through the first differential input pair 121 and a current that flows through the second differential input pair 122.

The PMOS transistors 105 and 106 form a load of the first differential input pair 121 and the second differential input pair 122 described above. A gate of the PMOS transistor 105 and a gate of the PMOS transistor 106 are connected to each other. A source of the PMOS transistor 105 and a source of the PMOS transistor 106 are connected to the power supply voltage 109. The gate of the PMOS transistor 105 and the gate of the PMOS transistor 106 are connected to each other to be connected to a drain of the PMOS transistor 105, a drain of the NMOS depletion transistor 101, and a drain of the NMOS transistor 103. A drain of the PMOS transistor 106 is connected to a drain of the NMOS depletion transistor 102 and a drain of the NMOS transistor 104. The drain of the PMOS transistor 106 is the output terminal 113.

In FIG. 2, operation of the differential amplifier circuit of the first embodiment is shown. In general, the differential amplifier circuit is used in negative feedback, and hence the non-inverting input terminal 112 and the inverting input terminal 111 are virtually short-circuited, with the result that the non-inverting input terminal 112 and the inverting input terminal 111 have almost the same voltage. This voltage is defined as a common-mode input voltage VCOM. In the graph of FIG. 2, the vertical axis is the common-mode input voltage VCOM, and indicates, by the use of rectangles with hatching, operation voltage ranges in VCOM of the first differential input pair 121 and the second differential input pair 122 arranged along the horizontal axis respectively.

The NMOS transistor 108 serves as a current source for supplying a current to the first differential input pair 121 when the NMOS transistor 107 serving as a selector switch is turned on, and serves as a current source for supplying a current to the second differential input pair 122 when the NMOS transistor 107 is turned off.

A voltage at which the operation of the first differential input pair 121 and the operation of the second differential input pair 122 are switched is referred to as a switching voltage V114. The switching voltage V114 is set within a range of the common-mode input voltage VCOM in which the first differential input pair 121 and the second differential input pair 122 both operate. The switching voltage V114 is applied from the switching voltage input 114 to the gate terminal of the NMOS transistor 107. The common-mode input voltage VCOM at which the NMOS transistor 107 is turned on is given by the following expression.

VCOM<V114−VTNE(107)−Vov(107)+VTNE(103)+Vov(103)

In this expression, VTNE denotes a threshold voltage of the NMOS enhancement transistors. A threshold voltage of the NMOS depletion transistors is denoted by VTND which is described later. Vov denotes an overdrive voltage required to cause current to flow. When the same type of element is used for the NMOS transistor 103 of the second differential input pair 122 and the NMOS transistor 107 serving as the selector switch, the NMOS transistor 103 and the NMOS transistor 107 have the same characteristics. When VTNE(107)=VTNE(103) and Vov(107)=Vov(103) are satisfied, the above-mentioned expression is given by the following expression.

VCOM<V114

As described above, when the common-mode input voltage VCOM falls below the switching voltage V114, the NMOS transistor 107 serving as the selector switch is turned on. At this time, the same gate-source voltage is applied to the NMOS depletion transistor 101 of the first differential input pair 121 and the NMOS enhancement transistor 103 of the second differential input pair 122.

Similarly, the same gate-source voltage is applied to the NMOS depletion transistor 102 of the first differential input pair 121 and the NMOS enhancement transistor 104 of the second differential input pair 122. However, the threshold voltage VTND of the NMOS depletion transistors is a voltage smaller than the threshold voltage VTNE of the NMOS enhancement transistors, and hence the first differential input pair 121 formed of the NMOS depletion transistors is applied with a larger overdrive current. As a result, a drain current from the NMOS transistor 108 serving as the current source is supplied to the first differential input pair 121.

When the common-mode input voltage VCOM exceeds the switching voltage V114, the NMOS transistor 107 serving as the selector switch is turned off. As a result, the drain current from the NMOS transistor 108 serving as the current source is supplied to the second differential input pair 122.

As described above, in the differential amplifier circuit of the first embodiment of the present invention, the NMOS transistor 107 serving as the selector switch is turned on and off depending on a value of the common-mode input voltage VCOM which is determined based on the voltage across the non-inverting input terminal 112 and the inverting input terminal 111. Through use of the selector switch, current is supplied from the current source to only one of the first differential input pair 121 formed of the NMOS depletion transistors and the second differential input pair 122 formed of the NMOS enhancement transistors. The first differential input pair and the second differential input pair do not operate at the same time, and hence an amplification factor is stabilized to reduce the possibility of deterioration of oscillation stability. With this, it is possible to solve the problem in that an amplification factor is greatly changed to increase the possibility of deterioration of oscillation stability. Consequently, a rail-to-rail input differential amplifier circuit having high oscillation stability can be provided.

### Second Embodiment

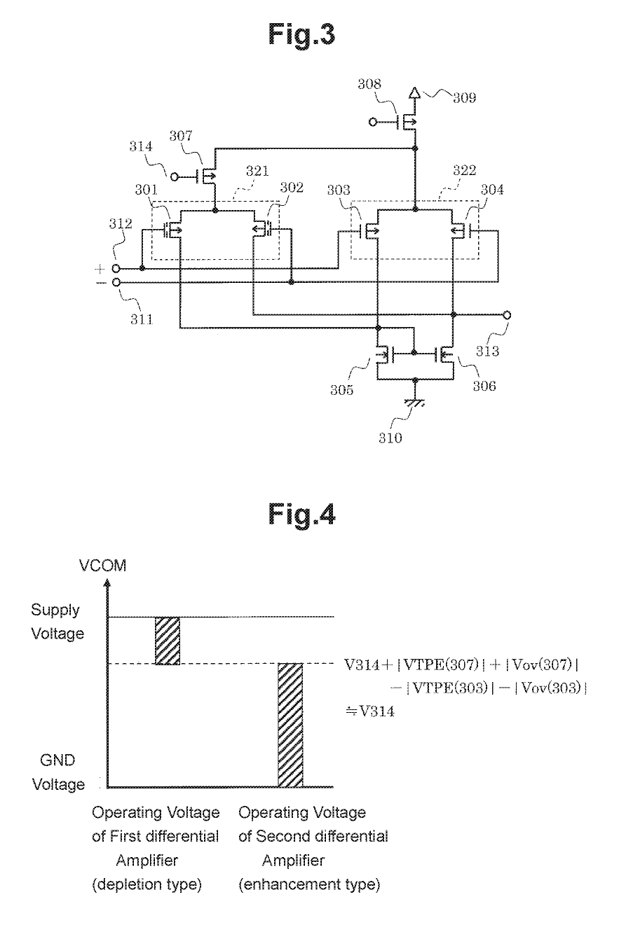

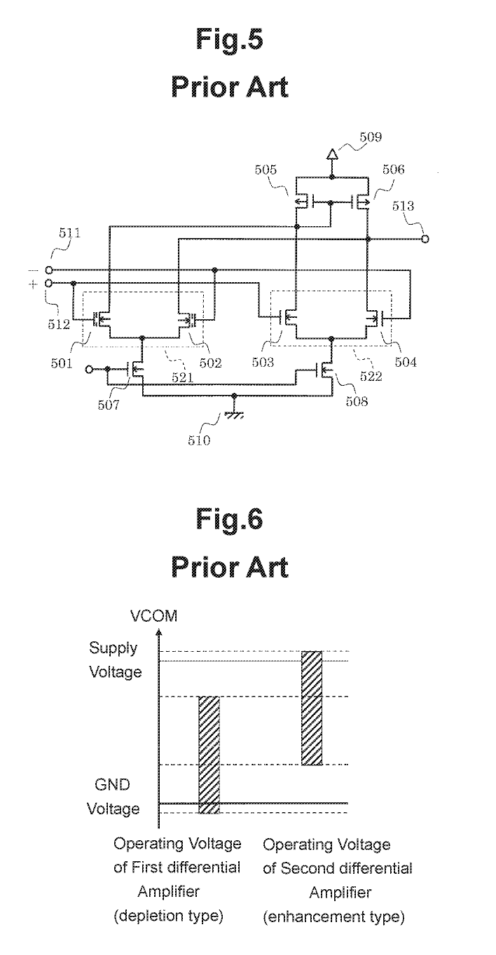

FIG. 3 is a circuit diagram for illustrating a differential amplifier circuit according to a second embodiment of the present invention.

The differential amplifier circuit of the second embodiment includes an inverting input terminal 311, a non-inverting input terminal 312, an output terminal 313, a power supply voltage 309, a GND voltage 310, PMOS depletion transistors 301 and 302, PMOS enhancement transistors 303, 304, 307, and 308, and NMOS enhancement transistors 305 and 306. The PMOS depletion transistors 301 and 302 form a first differential input pair 321. The PMOS transistors 303 and 304 form a second differential input pair 322.

The differential amplifier circuit of the second embodiment is obtained by making the following change to the differential amplifier circuit of the first embodiment. Specifically, the NMOS depletion transistors 101 and 102 which form the first differential input pair are replaced by the PMOS depletion transistors 301 and 302. The NMOS enhancement transistors 103 and 104 which form the second differential input pair are replaced by the PMOS enhancement transistors 303 and 304. The PMOS enhancement transistors 105 and 106 which form the load of the differential input pairs are replaced by the NMOS enhancement transistors 305 and 306. The NMOS enhancement transistor 107 serving as the selector switch is replaced by the PMOS enhancement transistor 307. The NMOS enhancement transistor 108 serving as the current source is replaced by the PMOS enhancement transistor 308. In short, the differential amplifier circuit according to the second embodiment is obtained by replacing the NMOS transistors by the PMOS transistors that form the differential amplifier circuit. The connections between the respective elements are the same except for polarities that are inverted from those of the first embodiment, and hence description thereof is omitted.

In FIG. 4, operation of the differential amplifier circuit of the second embodiment is shown. In FIG. 4, the vertical axis is the common-mode input voltage VCOM, and indicates, by the use of rectangles with hatching, operation voltage ranges in VCOM of the first differential input pair 321 and the second differential input pair 322 arranged along the horizontal axis respectively. The PMOS transistor 308 serves as a current source for the first differential input pair 321 when the PMOS transistor 307 serving as a selector switch is turned on, and serves as a current source for the second differential input pair 322 when the PMOS transistor 307 is turned off.

A voltage at which the operation of the first differential input pair 321 and the operation of the second differential input pair 322 are switched is referred to as a switching voltage V314. The switching voltage V314 is applied from a switching voltage input 314 to a gate terminal of the PMOS transistor 307. The common-mode input voltage VCOM at which the PMOS transistor 307 is turned on is given by the following expression.

VCOM>V314−|VTPE(307)|−|Vov(307)|+|VTPE(303)|+|Vov(303)|

In this expression, VTPE denotes a threshold voltage of the PMOS enhancement transistors. A threshold voltage of the PMOS depletion transistors is denoted by VTPD which is described later. When the same type of element is used for the PMOS transistor 303 of the second differential input pair 322 and the PMOS transistor 307 serving as the selector switch, the PMOS transistor 303 and the PMOS transistor 307 have the same characteristics. When VTPE(307)=VTPE(303) and Vov(307)=Vov(303) are satisfied, the above-mentioned expression is given by the following expression.

VCOM>V314

As described above, when the common-mode input voltage VCOM exceeds the switching voltage V314, the PMOS transistor 307 is turned on. At this time, the same gate-source voltage is applied to the PMOS depletion transistor 301 of the first differential input pair 321 and the PMOS enhancement transistor 303 of the second differential input pair 322. Similarly, the same gate-source voltage is applied to the PMOS depletion transistor 302 of the first differential input pair 321 and the PMOS enhancement transistor 304 of the second differential input pair 322. However, the threshold voltage VTPD of the PMOS depletion transistors is a voltage smaller than the threshold voltage VTPE of the PMOS enhancement transistors, and hence the first differential input pair 321 formed of the PMOS depletion transistors is applied with a larger overdrive current. As a result, a drain current from the PMOS transistor 308 serving as the current source is supplied to the first differential input pair 321.

When the common-mode input voltage VCOM falls below the switching voltage V314, the PMOS transistor 307 serving as the selector switch is turned off. As a result, the drain current from the PMOS transistor 308 serving as the current source is supplied to the second differential input pair 322.

As described above, in the differential amplifier circuit of the second embodiment of the present invention, the PMOS transistor 307 serving as the selector switch is turned on and off depending on a value of the common-mode input voltage VCOM which is determined based on the voltage across the non-inverting input terminal 312 and the inverting input terminal 311. Through use of the selector switch, current is supplied from the current source to only one of the first differential input pair 321 formed of the PMOS depletion transistors and the second differential input pair 322 formed of the PMOS enhancement transistors. The first differential input pair and the second differential input pair do not operate at the same time.

What is claimed is:

1. A differential amplifier circuit, comprising:
an inverting input terminal;
a non-inverting input terminal;
an output terminal;
a first differential input pair configured to receive input from the inverting input terminal and the non-inverting input terminal;
a second differential input pair configured to receive input from the inverting input terminal and the non-inverting input terminal, the second differential input pair including transistors that have a threshold value different from a threshold value of transistors included in the first differential input pair;
a current source configured to supply current to the second differential input pair; and
a switch provided between the first differential input pair and the current source, and is configured to be turned on and off in accordance with a voltage across the inverting input terminal and the non-inverting input terminal.

2. A differential amplifier circuit according to claim 1:
wherein the first differential input pair is formed of NMOS depletion transistors, the second differential input pair is formed of NMOS enhancement transistors, and the switch is formed of an NMOS enhancement transistor; and
wherein the switch is configured to be turned on and off in accordance with the voltage across the inverting input terminal and the non-inverting input terminal to supply current to one of the first differential input pair and the second differential input pair.

3. A differential amplifier circuit according to claim 1:
wherein the first differential input pair is formed of PMOS depletion transistors, the second differential input pair is formed of PMOS enhancement transistors, and the switch is formed of a PMOS enhancement transistor; and
wherein the switch is configured to be turned on and off in accordance with the voltage across the inverting input terminal and the non-inverting input terminal to supply current to one of the first differential input pair and the second differential input pair.
